(19) United States
(12) Patent Application Publication
(10) Pub. No.: US 2024/0377573 A1
(43) Pub. Date: Nov. 14, 2024

(54) Edgeless LED Display System

(71) Applicants: Mark W. Fuller, Sun Valley, CA (US); Garrett Young, Sun Valley, CA (US)

(72) Inventors: Mark W. Fuller, Sun Valley, CA (US); Garrett Young, Sun Valley, CA (US)

(21) Appl. No.: 18/614,498

(22) Filed: Mar. 22, 2024

Related U.S. Application Data
(60) Provisional application No. 63/454,484, filed on Mar. 24, 2023.

(51) Int. Cl. F21V 8/00; H01L 25/075; H01L 33/54

(52) U.S. Cl. CPC G02B 6/0073; H01L 25/0753; H01L 33/54

(57) ABSTRACT

An LED display system configured with peripheral light guides is disclosed. The system includes a PCB with a topside array of forward-facing LEDs emitting forward light, and a bottom side peripheral pattern of backward-facing LEDs emitting backward light. The backward light may be redirected to the forward direction around the perimeter of the LED display by a peripheral pattern of light guide elements. In this way, the light guide elements provide the outermost peripheral pixels of the LED display system.

### CROSS REFERENCE TO RELATED APPLICATION

This application claims the benefit of U.S. Provisional Application No. 63/454,484, filed Mar. 24, 2023, the contents of which are incorporated herein by reference.

### COPYRIGHT STATEMENT

This patent document contains material subject to copyright protection. The copyright owner has no objection to the reproduction of this patent document or any related materials in the files of the United States Patent and Trademark Office, but otherwise reserves all copyrights whatsoever.

### FIELD OF THE INVENTION

This invention relates to light emitting diode (LED) displays, including LED displays configured with light guides.

### BACKGROUND

Direct-view light emitting diode (LED) displays utilize arrays of LEDs to form arrays of self-illuminating display pixels. In the current market, these displays are often referred to as flat screens, or more specifically, direct-view LED flat screens. This is in contrast to liquid crystal displays (LCDs) wherein the display pixels are not self-illuminating, but instead require backlighting (often provided by LEDs positioned behind the LCD panel).

As is known in the art, each self-illuminating pixel in these types of arrays may typically be formed by one red (R), one green (G) and one blue (B) LED, either clustered together or formed integrally with one another. This may be referred to as an RGB pixel. The LEDs are mounted on printed circuit boards (PCBs) and voltage biases are applied to each RGB LED cluster to control the hue of light emitted from each corresponding RGB pixel.

The RGB LED cluster arrays may extend from edge-to-edge on a PCB with the outermost RGB LED clusters generally defining the edge of the display's viewable portion (the edge pixels). A desirable design criterion includes minimizing the space between the outermost RGB LED clusters and the outermost edges of the PCB so that the edge pixels are positioned as close as possible to the PCB's edge. This may be achieved by creating smaller and smaller RGB LED clusters.

The populated PCB is typically mounted within a thin outer frame for support while minimizing the non-illuminating gap portion between the edge pixels and the frame structure. In normal operating environments (e.g., indoors and with minimal moisture), the gap between the PCB and the frame may be quite small giving the LED display an appearance that the pixels extend to the very edge of the display. This may provide a very pleasing aesthetic and is often referred to as an edgeless, borderless and/or frameless display.

However, for LED displays designed to be operated outdoors, in harsh environments, or even submerged, the PCB, RGB LEDs and other components of the display must be waterproofed, often requiring the complete encapsulation of the PCB and LEDs within a suitable encapsulate (e.g., silicon). This encapsulation requires additional space to provide an adequate layer of protection to the internal devices of the display, and as such, requires an increased gap between the outer edges of the PCB and the frame. This increase may adversely affect the “edgeless” appearance of the display given the larger space of non-illuminating area around the display's perimeter.

Accordingly, there is a need for a direct-view LED display designed for use outdoors, e.g., in harsh environment and even submerged, wherein the display's outermost pixels extend to the display's outer frame with minimal gaps therebetween. That is, there is a need for an “edgeless” direct-view LED display that may be operated outdoors, in harsh environments and even submerged.

### SUMMARY

The present invention is specified in the claims as well as in the below description. Preferred embodiments are particularly specified in the dependent claims and the description of various embodiments.

According to one aspect, one or more embodiments are provided below for a display system including a LED panel assembly, a light guide assembly, a housing assembly, an optics assembly, and an electronics assembly. The LED panel assembly may include a PCB including a front side populated with a plurality of front side LEDs, and a back side opposite the front side and populated with a plurality of back side LEDs. The front side LEDs are configured to emit first light in a first direction, e.g., in a forward direction, and the back side LEDs are configured to emit second light in a second direction, e.g., in a reverse direction. The front side LEDs may be arranged in an array across the front side of the LED panel and the back side LEDs may be arranged along the outer periphery of the LED panel. The light guide assembly is configured to redirect the second light emitted by the second LEDs from the second direction to the first direction.

In another aspect of the invention, the LED panel assembly may be arranged within a housing for support and with the peripheral edges of the LED panel assembly separated from an inner wall of the housing by a gap. The light guide assembly may include one or more light guides, each configured with a corresponding back side LED, and configured to redirect the second light from the back side to the front side through the gap.

In another aspect of the invention, the display system includes at least one printed circuit board (PCB) including a PCB first side and a PCB second side opposite the PCB first side, at least one first light emitting diode (LED) configured with the PCB first side and adapted to emit first light in a first direction, at least one second LED configured with the PCB second side and adapted to emit second light in a second direction, and at least one first light guide configured with the at least one second LED and adapted to redirect at least a portion of the second light to the first direction as redirected light, wherein the first light and the redirected light combine to form a total emitted light.

In some embodiments, the second direction may be opposite the first direction.

In some embodiments, the system comprising a frame, wherein the at least one PCB is configured within the frame, wherein a peripheral edge of the at least one PCB is separated from the frame by a gap, and wherein the at least one first light guide is adapted to emit the redirected light through the gap.

In some embodiments, the at least one second LED is positioned adjacent to the peripheral edge and adapted to emit second light into an input of the at least one first light guide.

In some embodiments, the at least one first light guide is coupled to the frame.

In some embodiments, the gap includes an encapsulate.

In some embodiments, the system includes an optics assembly adapted to affect the first light and/or the redirected light.

In some embodiments, the at least one light guide includes one or more reflective prisms.

In some embodiments, the one or more reflective prisms includes a first 45° reflective prism and a second 45° reflective prism opposing the first 45° reflective prism.

In some embodiments, the at least one first light guide redirects the at least a portion of the second light 180°.

In some embodiments, the at least one first LED includes an array of the at least one first LEDs and the at least one second LED includes a plurality of the at least one second LEDs arranged about a periphery of the at least one PCB.

In some embodiments, the at least one first light guide includes a plurality of the at least one first light guides and wherein each one of the plurality of the at least one second LEDs is configured with a corresponding one of the plurality of the at least one first light guides.

Other aspects and embodiments of the invention are discussed herein.

### BRIEF DESCRIPTION OF THE DRAWINGS

Various other objects, features and attendant advantages of the present invention will become fully appreciated as the same becomes better understood when considered in conjunction with the accompanying drawings, in which like reference characters designate the same or similar parts throughout the several views, and wherein:

FIGS. 1-2 show aspects of a LED display system according to exemplary embodiments hereof;

FIGS. 3-5 show aspects of an LED panel assembly according to exemplary embodiments hereof;

FIG. 6 shows aspects of a light guide assembly according to exemplary embodiments hereof;

FIG. 7 shows aspects of a light guide element according to exemplary embodiments hereof;

FIG. 8 show aspects of an LED display system according to exemplary embodiments hereof;

FIG. 9 shows aspects of a light guide assembly according to exemplary embodiments hereof; and

FIG. 10 show aspects of combined LED display systems according to exemplary embodiments hereof.

### DETAILED DESCRIPTION OF EXEMPLARY EMBODIMENTS

As used herein, unless used otherwise, the following terms and abbreviations may generally have the following meanings:

A pixel is a basic unit of programmable color on a display or in a computer image, and in general, each pixel of a direct-view LED display may comprise one or more LEDs. For color displays, each pixel may include red, green and blue (RGB) clustered or integrally combined LED structures that together emit a blended hue of color. For white light displays, each pixel may include one or more white light LEDs that may emit white light.

The term pixel density represents the number of physical pixels per inch (PPI) or other unit area on a screen or display of a device. The term also may be referred to as pixels per inch or PPI.

The term pixel pitch describes the density of the pixels on an LED display and correlates with resolution. Sometimes referred to as pitch or dot pitch, the pixel pitch is the distance measured (typically in millimeters) from the center of a first pixel to the center of an adjacent pixel. As such, pixel pitch indicates the amount of space between two pixels, and a smaller pixel pitch generally equates to higher pixel density and improved screen resolution.

For purposes of this specification, the term LED may represent a single LED or a cluster of LEDs (e.g., one red, one green and one blue (RGB) LEDs) that may constitute a single pixel (e.g., an RGB pixel).

In general, the system according to embodiments hereof provides an LED panel display. In some embodiments, the LED display is a direct-view LED display with self-illuminating pixels, and therefore requires no backlighting. In some embodiments, the LED display is submergible and may be configured with other LED displays to form a composite display (e.g., a video wall or surface).

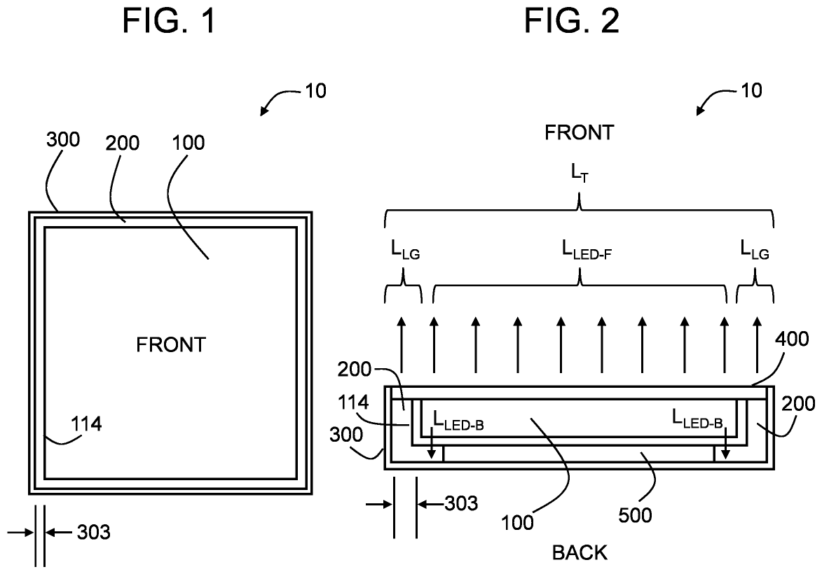

FIG. 1 shows a generalized top view of the system 10 and FIG. 2 shows a generalized side view of the same. In an exemplary embodiment hereof as shown, the LED display system 10 (also referred to herein as simply the system 10) includes an LED panel assembly 100, a light guide assembly 200, a housing assembly 300, an optics assembly 400, and an electronics assembly 500.

In general, as shown in FIG. 2, the front of the LED panel assembly 100 emits forward light L_{LED-F}. This forward light L_{LED-F} is controlled by the system 10 to form the images (e.g., video) that the LED panel display 100 provides to its viewers. However, because the outer edge 114 of the LED panel assembly 100 may be separated from the inner wall of the housing assembly 300 by a small gap 303, and because the front of the LED panel assembly 100 may not provide light in this gap area, the “edgeless” appearance of the display system 10 may be compromised. To solve this problem, the LED display system 10 provides rear-facing LEDs configured with a light guide assembly 200 within the gap 303 to provide illumination therein. As such, the “edgeless” appearance of the display system 10 may be retained.

In some embodiments, LEDs positioned across the front of the LED panel assembly 100 emit forward light L_{LED-F} and LEDs generally positioned around the outer periphery of the back of the LED panel assembly 100 emit backward light L_{LED-B}. The light guide assembly 200 is generally configured between the outer edge 114 of the PCB 102 and the inner wall of the frame 300 (e.g., within the gap 303). In this arrangement, the light guide assembly 200 collects the backward light L_{LED-B} and redirects it through the gap 303 to the outer perimeter of the front side as redirected light L_{LG}. Accordingly, as shown in FIG. 2, the total viewable light LT emitted from the front of the display system 10 may equal the forward light L_{LED-F} plus the redirected light L_{LG}.

In some embodiments, the total viewable light LT emanating from the front of the system 10 forms a complete image (e.g., video) that is provided to the viewer. As such, as shown in FIG. 2, the forward light L_{LED-F} from the forward-facing LEDs may generally form the inner portion of the displayed image and the redirected light L_{LG} from the rear-facing LEDs may generally form the outer peripheral portion of the displayed image. In this way, the combined forward light L_{LED-F} and redirected light L_{LG} together form the complete displayed image (as the total viewable light LT).

In other embodiments, it also is contemplated that the redirected light L_{LG} include other types of light that may not necessarily be a part of the displayed image (that is, not a part of the video). For example, in some embodiments the redirected light L_{LG} may include hues of light (e.g., a tapered gray to black hue) designed to minimize the appearance of the gap 303 without necessarily providing a portion of the displayed image. The forward-facing LEDs, the rea-facing LEDs, and the light guide assembly 200 will be described in detail in other sections.

The LED panel assembly 100 and the light guide assembly 200 may be housed in the housing assembly 300, and the optics assembly 400 may be adapted to affect the emitted light LT as required. The electronics assembly 500 may provide electrical signals to the LED panel assembly 100 to be converted and/or translated into emitted light (e.g., video images), in addition to providing power to the system 10 and meeting other requirements thereof.

The system 10 may include other elements and components as necessary to fulfill its functionalities as described herein or otherwise. The schematics of FIGS. 1 and 2 are meant only to demonstrate a general arrangement of elements and are not meant to represent the relative sizes, shapes, orientations, or locations of the elements.

### LED Panel Assembly 100

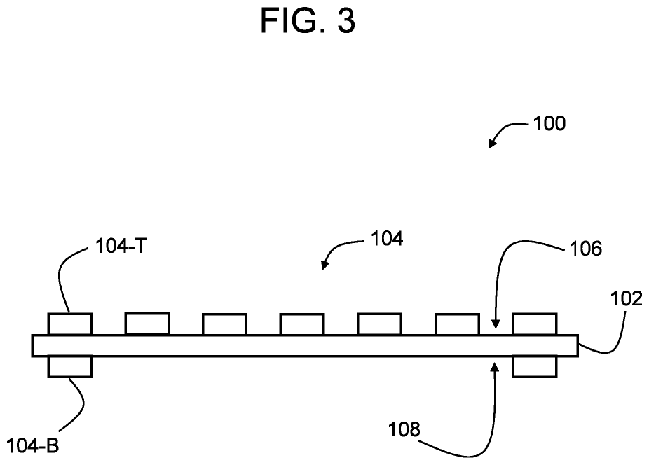

In an exemplary embodiment hereof as shown in FIG. 3, the LED panel assembly 100 may include one or more printed circuit board(s) (PCB) 102 populated with LEDs 104 and other electrical components (e.g., resistors, capacitors, inductors, transistors, amplifiers, ICs, etc.) as required for the operation of the LEDs 104. Given the high operational temperatures often associated with LEDs, the PCB 102 may preferably comprise an aluminum PCB that transfers heat away from the LEDs 104. This may allow for higher densities of mounted LEDs 104 while ensuring each diode's longevity. However, other types of PCBs 102 also may be used (e.g., fiberglass, composite epoxy, or other laminate materials). The PCB 102 may include single layer PCBs and/or multi-layer PCBs, and the PCBs 102 may be rigid, flexible, flex-rigid or any combinations thereof. It is understood that the LEDs 104 may be mounted to the PCBs 102 using any method, such as, without limitation, chip-on-board, packaging (e.g., through hole (T-packed), surface mounted, etc.), and/or using other methods.

FIG. 3 is a generalized side view of the LED panel assembly 100. In a preferred or exemplary embodiment, as shown in FIG. 3, the LED panel assembly 100 may include a multi-layered PCB 102 (e.g., two, three, four or more layers) with a top side 106 and a bottom side 108. The top side 106 correlates to the front of the LED panel assembly 100 as shown in FIGS. 1 and 2, and the back side correlates to the back of the LED panel assembly 100. The top side 106 may include a pattern of topside LEDs 104-T and the bottom side 108 may include a pattern of bottom side LEDs 104-B. As described above, each LED 104-T/B preferably forms a single pixel (e.g., an RGB pixel). Intermediary layers of the PCB 102 (if they exist) may provide power and ground to the LEDs 104-T/B.

The LED panel assembly 100 also may include two or more individual PCBs 102 arranged face-to-face. In this way, a first PCB 102 may provide the top side 106 and a second PCB 102 may provide the bottom side 108.

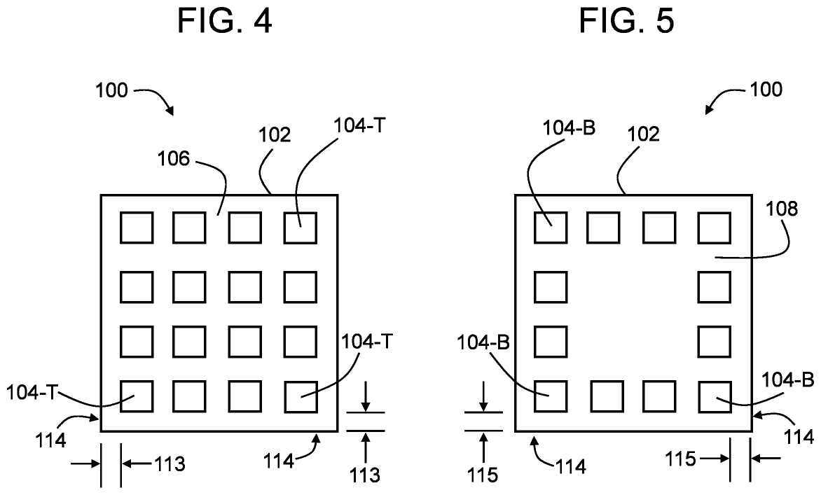

In some embodiments as shown in FIG. 4, the topside pattern of LEDs 104-T may include an edge-to-edge n×m array of LEDs 104-T that generally forms a topside array of pixels, with n equal to the number of rows of LEDs 104-T and m equal to the number of columns of LEDs 104-T. The n×m array of LEDs 104-T emits forward light L_{LED-F} that generally forms the inner portion of the forward displayed image (as shown in FIG. 2). The topside array of LEDs 104-T may extend across the PCB 102 from edge-to-edge (e.g., from left to right and top to bottom) and the gaps 113 between the outer edges 114 of the PCB 102 and the outermost LEDs 104-T are preferably reduced and/or minimized.

While FIG. 4 depicts a 4×4 array of LEDs 104-T, this arrangement is meant for demonstration only, and the topside LED panel 110 preferably includes an adequate pixel density for a desired resolution. In some embodiments hereof, the topside array of pixels may include a pixel density of about 100, 300, 600, 1000, 1300, 1600, 2000, 2200 or greater. The topside array of pixels may include any desired pixel density and the scope of the present invention regarding the system 10 is not limited in any way by the pixel density that it may provide.

In some embodiments as shown in FIG. 5, the bottom side pattern of LEDs 104-B may include a peripheral pattern of LEDs 104-B that generally forms a bottom side periphery of pixels. The peripheral pattern of LEDs 104-B may extend from top to bottom and side to side along the periphery of the PCB 102 and may include a width of one or more LEDs 104-B. The peripheral pattern of LEDs 104-B generally emits backward light L_{LED-B} that when redirected as redirected light L_{LG} generally forms the outer peripheral portion of the forward displayed image (as shown in FIG. 2). In some embodiments, each of the bottom LEDs 104-B may be aligned vertically with a corresponding peripheral topside LED 104-T as shown, but other relative positions of the bottom LEDs 104-B and topside LEDs 104-T also may be used. It is preferred that the gaps 115 between the outer edges 114 of the PCB 102 and the outermost LEDs 104-B be reduced or minimized.

In some embodiments, the backward light L_{LED-B} redirected through the gap 303 to the outer perimeter of the front side as redirected light L_{LG} includes pixel information that completes the outer peripheral portion of the overall forward displayed image provided by the total viewable light LT. Accordingly, the pixel information provided by the backward light L_{LED-B} is preferably emitted by the rear-facing LEDs in the proper orientation and format such that after it has been redirected into redirected light L_{LG} and added to the forward light L_{LED-F} at the front of the LED display 100, the combined forward light L_{LED-F} and redirected light L_{LG} together form a complete and seamless displayed image without gaps, seams, or other undesirable visual effects.

That is, the redirected light L_{LG} represents a continuation of the image provided by the forward light L_{LED-F}. For example, if the periphery of the forward light L_{LED-F} provides an image of most of a car, the redirected light L_{LG} may provide an image of the rest of, or another art of, the car that is not shown in the image provided by the forward light L_{LED-F}.

The topside and/or bottom side LEDs 104-T/B may include any adequate type or combination of types of emissive LEDs such as organic LEDs (OLEDs), microLEDs (e.g., GaN) and/or any other types of LEDs that may provide the required luminescence (preferably RGB).

### Light Guide Assembly 200

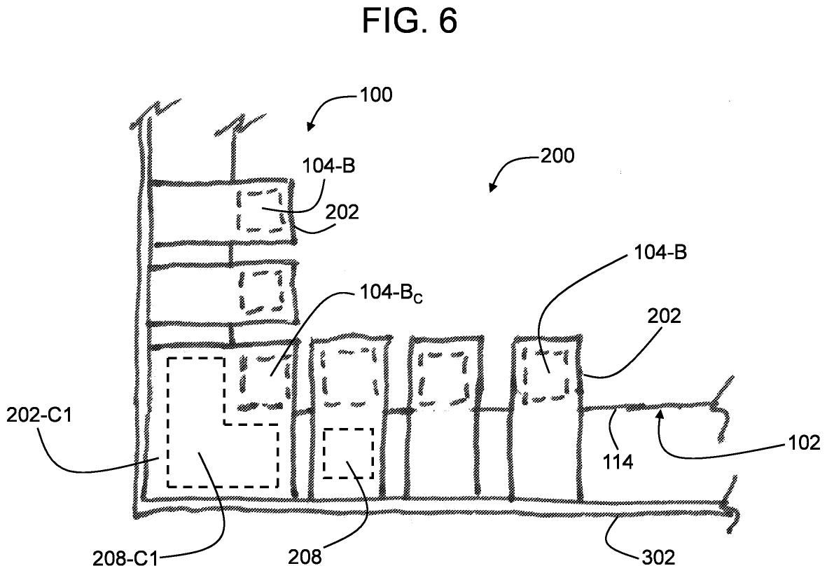

FIG. 6 shows a generalized bottom view of a corner portion of the LED panel assembly 100 configured with a corresponding portion of the light guide assembly 200. In an exemplary embodiment hereof as shown in FIG. 6, the light guide assembly 200 may include one or more light guide elements 202 that may each correspond to, and be aligned with, a respective bottom side LED 104-B (a bottom side pixel). In some embodiments, each light guide element 202 may include a light pipe or other type of light waveguide. The purpose of each light guide element 202 may be to collect backward emitted light L_{LED-B} from a corresponding bottom side LED 104-B and redirect it to the perimeter of the top side 106 of the PCB 102 as forward light L_{LG} (see also FIG. 2).

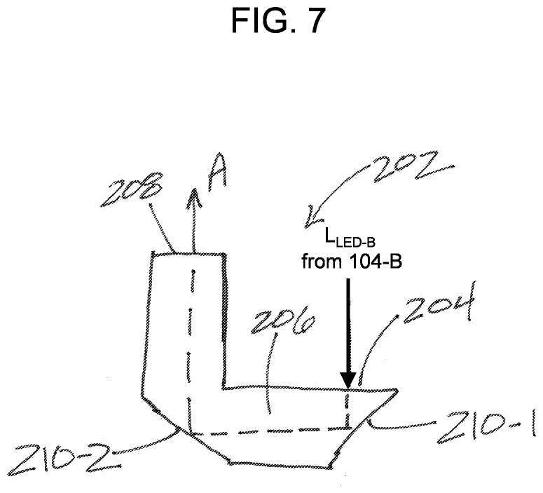

FIG. 7 shows a generalized side view of a light guide element 202. As shown, in some embodiments, a light guide element 202 may include an input 204, a body 206, and an output 208. As depicted by the arrow A, light from a bottom side LED 104-B may enter the input 204 of a corresponding light guide element 202, pass through the light guide element's body 206, and exit its output 208. Accordingly, effective flux coupling and light transfer from the bottom side LED 104-B into the light guide element 202 is preferred. As known in the art, this may be achieved with proper design choices regarding the interface between each LED 104-B and the input 204 of a corresponding light guide element 202.

For example, for surface mount devices (SMD) LEDs 104-B having a flat light emitting surface, the entrance end 204 of the light guide 202 may include a smooth flat surface. In this case, the light guide's entrance end 204 may be placed over and/or in close proximity to the light emitting surface of the SMT LED 104-B, with the distance between the LED 104-B and the input 204 chosen to result in the desired light capture. In addition, the entrance end 204 may be slightly larger than the emitting surface of the LED 104-B to optimize flux capture, considering the Fresnel losses across the air gap.

In another example, a lens may be positioned between the LED 104-B output and the light guide input 204 to focus the flux from the LED 104-B into the guide element 204.

In another example, the LED 104-B may be positioned inside the light guide surface-to-air boundary (e.g., within an end cavity in the light guide element 202), and the air gap between the LED 104-B output and the input surface 204 may be minimized and/or filled with epoxy to minimize Fresnel losses.

In another example, the input surface 204 of the light guide element 202 may be contoured (e.g., concave) to match the output radiation pattern of the LED 104-B.

The above-described design considerations for the interface between the LED 104-B and the light guide element 202 are presented for demonstration and the interface between the LED 104-B and the light guide element 202 may be designed using any adequate design considerations as required or preferred. It is understood that the scope of the present invention regarding the system 10 is not limited in any way by the types of LED 104-B to light guide 202 interfaces implemented within the system 10.

In some embodiments, each light guide element 202 may utilize total internal reflection (TIR) to transmit the captured light from the input 204 to the output 208 with minimal loss. Accordingly, the sides parallel to the direction of light travel within the light guide element 202 are preferably smooth (mirror-like) to affect TIR. These sides also may be painted with white-light reflecting paint to internally reflect any diagonal rays traveling at angles less than the critical angle.

In some embodiments, the light guide elements 202 may be cylindrical (e.g., circular or oval), rectangular (e.g., square), conical (e.g., increasing in size from entrance 204 to exit 208 or vice versa), or any other shape (e.g., arrow, star shaped, quarter moon, etc.). For rectangular guides 202, the corners may preferably have a radius greater than 0.5 mm (0.020 in.) to assure illumination in the corners. The shape of the light guide 202 may gradually change along its length (e.g., from circular at the entrance 204 to square at the exit end 202 or vice versa). The light guide elements 202 may comprise glass, polycarbonate, other suitable materials and/or any combinations thereof.

In some embodiments, each light guide element 202 redirects captured light from its input 204 approximately 180° to its output 208. This is depicted by arrow A in FIG. 7. Accordingly, the light guide elements 202 may include a series of reflective prisms, smooth bends, other redirecting structures, or any combinations thereof. In one implementation as shown, the light guide elements 202 may each include two face-to-face (e.g., opposing) reflective prisms 210-1, 210-2 (e.g., each at 45° with respect to the direction of light travel within the guide 202) to affect the 180° redirection. In other implementations, the light guide elements each include a smooth 180° bend with the bend radius preferably equal to or greater than twice the diameter of the light guide 202 to minimize light loss.

In some embodiments, the exit end 208 may be diffused and textured with random critical angles across its surface to provide a high probability that the light rays may escape and be emitted upwards (e.g., as light L_{LG}). Other design techniques also may be used to facilitate the emission of the guided light out of the exit end 208 as desired.

In addition, it is understood that depending on the type and configuration of light guide assembly 200 used, the pixel information provided by the backward light L_{LED-B} is preferably emitted by the bottom side LEDs 104-B in the proper orientation and format such that after it has been redirected into redirected light L_{LG} and added to the forward light L_{LED-F} at the front of the LED display 100, the combined forward light L_{LED-F} and redirected light L_{LG} together form a complete and seamless displayed image without gaps, seams, or other undesirable visual effects. For example, in some embodiments, the pixel information provided by the backward light L_{LED-B} may be mirrored, not mirrored, flipped horizontally, flipped vertically, at the same orientation, and/or oriented in any way with respect to the redirected light L_{LG}. It also is contemplated that the pixel information in the redirected light L_{LG} be processed (e.g., reoriented, mirrored, flipped, etc.) at the output of any light guide 202 as necessary to form a seamless forward image when combined with the forward light L_{LED-F}.

### LED Display System 10

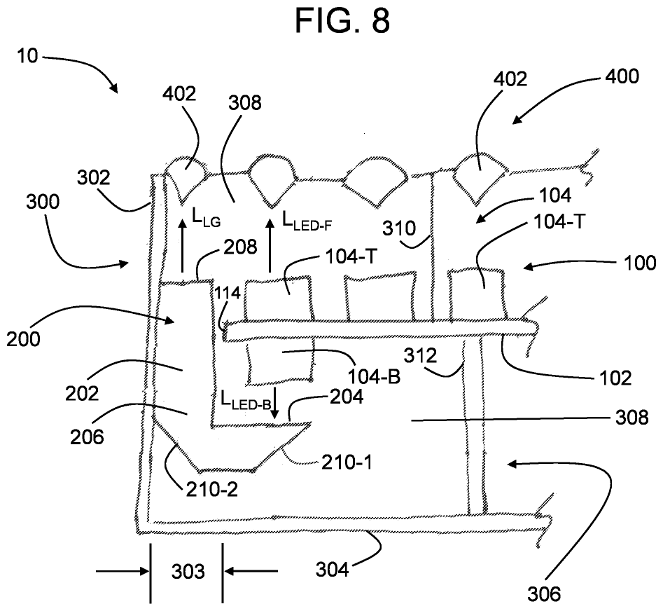

FIG. 8 shows a generalized side view of the system 10. In some embodiments as shown in FIG. 8, the LED panel assembly 100 is configured with the light guide assembly 200 within the housing assembly 300. The housing assembly 300 may include an outer peripheral frame 302 and a bottom 304 defining an inner volume 306. In some embodiments, a gap 303 may exist between the peripheral edge 114 of the PCB 102 and the outer peripheral frame 302

In some embodiments, the LED panel assembly 100 and the light guide assembly 200 may be held within the inner volume 306 by an encapsulate 308 such as silicon, polyurethane, other types of encapsulates and/or any combinations thereof. The encapsulate 308 is preferably transparent, waterproof, UV resistant, impact resistant, abrasion resistant, vibration resistant, dirt and dust resistant, fuel and solvent resistant and/or durable. The encapsulate 308 preferably provides a hermetic seal to the LEDs 104 and other components held within. In this way, the LED display system 10 may be used outdoors and in harsh conditions, submerged underwater, and otherwise used in specialty or varied environments.

In some embodiments, suspension lines 310 and/or PCB supports 312 may be used to provide additional support to the encapsulated LED panel assembly 100 and/or light guide assembly 200 within the housing 300.

As shown, the input 204 of each light guide element 202 is adjacent and aligned with a corresponding bottom side LED 104-B to capture downward light L_{LED-B}. Downward light L_{LED-B} within the guide 202 is redirected 90° outward from the PCB 102 by the first prism 210-1 within the guide's body 208, and then 90° upward by the second prism 210-2 (also see FIG. 7). The upward light may then exit the output 208 of the light guide element 202 as forward light L_{LG}. From there the forward light L_{LG} from the light guide 202 joins the forward light L_{LED-T} from the front 106 of the panel assembly 100 to form the combined forward light LT.

In some embodiments, as shown in FIG. 8, at least a portion of the outer wall of each light guide element 202 may be bonded directly to the inner wall of the outer peripheral frame 302 so that there is no gap between the pixel provided by the light guide element 202 and the frame 302. In this way, the outermost pixels of the display system 10 provided by the peripheral pattern of light guide elements 202 generally defines the outer lighted perimeter of the system 10. The width of the peripheral frame 302 may be reduced and/or minimized so that the display system 10 appears to be edgeless.

In some embodiments, the bonding between each light guide element 202 and the inner wall of the outer peripheral frame 302 also may provide additional lateral support to the overall structure of the display system 10.

In some embodiments, the pixel pitch between each topside pixel provided by the output 208 of each light guide element 202 and an adjacent pixel provided by an adjacent topside LED 104-T is generally equal to the pixel pitch between adjacent topside LEDs 104-T so that the total combined pixels on the topside are spaced symmetrically throughout.

Returning to FIG. 6, in some embodiments, a corner-positioned light guide element 202-C1 may capture light L_{LED-B} from a corner LED 104-B_{C} and may then expand this light laterally to provide a topside corner output 208-C1 with an output surface area of approximately three pixels. In this way, the corner light guide element 202-C1 may fill the full topside corner of the display system 10 with forward emitted light L_{LG}.

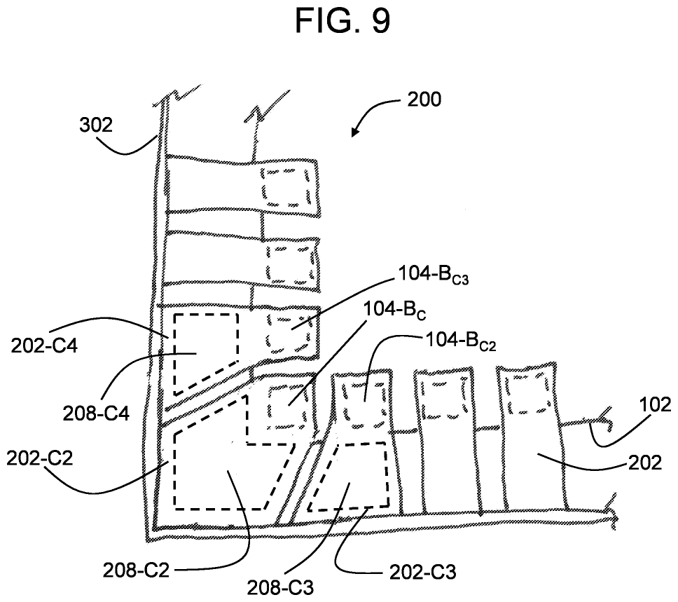

In an alternative embodiment, as shown in FIG. 9, a corner positioned light guide element 202-C2 may capture light L_{LED-B} from a corner LED 104-B_{C} and may then expand this light laterally to provide a topside output 208-C2 with an output surface area of approximately two pixels. In addition, a first corner-adjacent light guide element 202-C3 may capture light L_{LED-B} from a first corner-adjacent LED 104-B_{C2} and may then expand this light laterally to provide a topside output 208-C3 with an output surface area of approximately one and one-half pixels, and a second corner-adjacent light guide element 202-C4 may capture light L_{LED-B} from a second corner-adjacent LED 104-B_{C3} and may then expand this light laterally to provide a topside output 208-C4 with an output surface area of approximately one and one-half pixels. In this way, the combination of corner light guide element 202-C2 and corner-adjacent light guide elements 202-C3 and 202-C4 may fill the full topside corner of the display system 10 with forward emitted light.

The above embodiments regarding the corner lighting are meant for demonstration and it is understood that other configurations, sizes, shapes, and/or arrangements of light guide elements 202 also may be used to accomplish the same or similar result. It also is understood that each corner of the display system 10 may be filled with forward emitting light from any number and arrangement of light guide elements 202 as necessary.

In some embodiments, the electronics assembly 500 may supply electrical bias to the individual topside and bottom side LEDs 104-T/B to control the LED emissions. In some embodiments, known as a passive-matrix scheme, the individual anodes and cathodes of the LEDs 104-T/B are connected by perpendicular conducting strips, and the electronics assembly 500 applies voltages to the rows and columns of LEDs 104-T/B that are necessary to control which pixels to turn on and the resulting hues of color. In other embodiments, the electronics assembly 500 includes a thin-film transistor (TFT) array to supply power to the individual LEDs 104-T/B to control the light emissions. Other power providing arrangements also may be used. The electronics assembly 500 also may provide power to other elements and/or components of the system 10 as required.

In some embodiments, as shown in FIG. 8, the optics assembly 400 may include one or more optical elements 402 positioned to affect the forward light L_{LG}, L_{LED-F} and/or L_{T}. For example, one or more optical elements 402 may be positioned at the output of the topside LEDs 104-T, at the output 208 of the light guide elements 402, and/or in other areas. In some embodiments, the optical elements 402 may include optical lenses (e.g., wide angle), optical diffusers, other types of optical elements and any combinations thereof. In some embodiments, one optical element 402 may be provided for each pixel provided by the topside LEDs 104-T and/or the light guide elements 202. In other embodiments, an optical element 402 may be provided for a plurality of pixels provided by the topside LEDs 104-T and/or by the light guide elements 202, with one or more optical elements 402 affecting the forward light L_{LG}, L_{LED-F} and/or L_{T}.

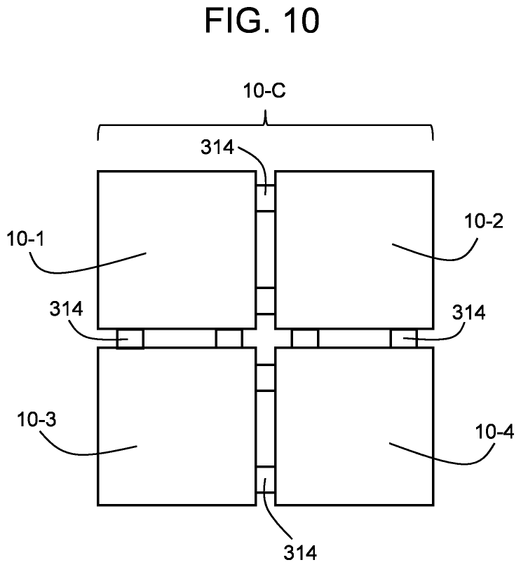

In some embodiments, as shown in FIG. 10, the housing assembly 300 may include attachment mechanisms 314 adapted to attach a first display system 10-1 to a second display system 10-2. In some embodiments, the first and second display systems 10-1, 10-2 may be configured side-by-side to form a composite display system 10-C with twice the pixel density of the individual first and second display systems 10-1, 10-2. It is understood that any number of display systems 10-n may be combined to form a composite display system 10-C of any size and/or shape (e.g., a video wall). The attachment mechanisms 314 may include brackets, latches, guide pins, magnets, channels, other types of attachment mechanisms 314 and any combination thereof. A preferred design criteria may include minimizing the width of the attachment mechanisms 314 and/or integrating the attachment mechanisms 314 into the frame assembly 300 so as to minimize the gaps between the display systems 10-n.

While the above descriptions primarily described the display system 10 as rectangular (or square), the display system 10 may be formed as any shape (e.g., circular, octagonal, etc.) and/or as any combination of shapes, and the scope of the system 10 is not limited in any way by the shape or form that the system 10 may include.

Notably, the current manufacturing processes of a PCB having LEDs mounted thereon strive to reduce size of the frame surrounding the PCB with a top-down build. As such, the top surface of the PCB may remain upward throughout the manufacturing process. However, the present invention represents a significant departure from typical top-down builds because it includes bottom facing LEDs. As such, the PCB may need to be flipped over during the manufacturing process so that the bottom of the PCB may face upward while the LEDs that are ultimately bottom facing are attached to the PCB. It also is contemplated that the PCB may be populated with topside LEDs from above and bottom side LEDs from below, and/or by using any combinations thereof.

Current designs also strive to reduce the size of the frame surrounding the PCB by using smaller LEDs around its periphery. This may be disadvantageous because such LEDs may be fragile and/or may be prone to damage because of their peripheral location. However, in the present invention, the bottom-facing LEDs 104-B and light pipes 202 may replace what would otherwise be the outermost forward-facing LEDs on the top of the PCB. To this end, in the present invention, the light pipes 202 that are located on the periphery of the PCB may be generally sturdier than LEDs that would otherwise be located in these positions. As such, the present invention eliminates the need smaller more fragile LEDs around the periphery of the LED display 100.

Because of its ruggedness, the display system 10 of the present invention may be used as an element within various multimedia displays, such as water and lighting displays. For example, the display system 10 may be incorporated into the Water Drop TV Screen display, as described in U.S. Ser. No. 16/137,239, the entire contents of which are incorporated by reference as if fully set forth herein.

It is understood that any aspect and/or element of any embodiment of the system 10 described herein may be combined with any other aspect and/or element of any other embodiment of the system 10 to form additional embodiments of the system 10 all of which are within the scope of the system 10.

Those of ordinary skill in the art will appreciate and understand, upon reading this description, that embodiments hereof may provide different and/or other advantages, and that not all embodiments or implementations need have all advantages.

Where a process is described herein, those of ordinary skill in the art will appreciate that the process may operate without any user intervention. In another embodiment, the process includes some human intervention (e.g., a step is performed by or with the assistance of a human).

As used herein, including in the claims, the phrase “at least some” means “one or more,” and includes the case of only one. Thus, e.g., the phrase “at least some ABCs” means “one or more ABCs”, and includes the case of only one ABC.

As used herein, including in the claims, term “at least one” should be understood as meaning “one or more”, and therefore includes both embodiments that include one or multiple components. Furthermore, dependent claims that refer to independent claims that describe features with “at least one” have the same meaning, both when the feature is referred to as “the” and “the at least one”.

As used in this description, the term “portion” means some or all. So, for example, “A portion of X” may include some of “X” or all of “X”. In the context of a conversation, the term “portion” means some or all of the conversation.

As used herein, including in the claims, the phrase “using” means “using at least,” and is not exclusive. Thus, e.g., the phrase “using X” means “using at least X.” Unless specifically stated by use of the word “only”, the phrase “using X” does not mean “using only X.”

As used herein, including in the claims, the phrase “based on” means “based in part on” or “based, at least in part, on,” and is not exclusive. Thus, e.g., the phrase “based on factor X” means “based in part on factor X” or “based, at least in part, on factor X.” Unless specifically stated by use of the word “only”, the phrase “based on X” does not mean “based only on X.”

In general, as used herein, including in the claims, unless the word “only” is specifically used in a phrase, it should not be read into that phrase.

As used herein, including in the claims, the phrase “distinct” means “at least partially distinct.” Unless specifically stated, distinct does not mean fully distinct. Thus, e.g., the phrase, “X is distinct from Y” means that “X is at least partially distinct from Y,” and does not mean that “X is fully distinct from Y.” Thus, as used herein, including in the claims, the phrase “X is distinct from Y” means that X differs from Y in at least some way.

It should be appreciated that the words “first,” “second,” and so on, in the description and claims, are used to distinguish or identify, and not to show a serial or numerical limitation. Similarly, letter labels (e.g., “(A)”, “(B)”, “(C)”, and so on, or “(a)”, “(b)”, and so on) and/or numbers (e.g., “(i)”, “(ii)”, and so on) are used to assist in readability and to help distinguish and/or identify, and are not intended to be otherwise limiting or to impose or imply any serial or numerical limitations or orderings. Similarly, words such as “particular,” “specific,” “certain,” and “given,” in the description and claims, if used, are to distinguish or identify, and are not intended to be otherwise limiting.

As used herein, including in the claims, the terms “multiple” and “plurality” mean “two or more,” and include the case of “two.” Thus, e.g., the phrase “multiple ABCs,” means “two or more ABCs,” and includes “two ABCs.” Similarly, e.g., the phrase “multiple PQRs,” means “two or more PQRs,” and includes “two PQRs.”

The present invention also covers the exact terms, features, values and ranges, etc. in case these terms, features, values and ranges etc. are used in conjunction with terms such as about, around, generally, substantially, essentially, at least etc. (i.e., “about 3” or “approximately 3” shall also cover exactly 3 or “substantially constant” shall also cover exactly constant).

As used herein, including in the claims, singular forms of terms are to be construed as also including the plural form and vice versa, unless the context indicates otherwise. Thus, it should be noted that as used herein, the singular forms “a,” “an,” and “the” include plural references unless the context clearly dictates otherwise.

Throughout the description and claims, the terms “comprise”, “including”, “having”, and “contain” and their variations should be understood as meaning “including but not limited to”, and are not intended to exclude other components unless specifically so stated.

It will be appreciated that variations to the embodiments of the invention can be made while still falling within the scope of the invention. Alternative features serving the same, equivalent or similar purpose can replace features disclosed in the specification, unless stated otherwise. Thus, unless stated otherwise, each feature disclosed represents one example of a generic series of equivalent or similar features.

The present invention also covers the exact terms, features, values and ranges, etc. in case these terms, features, values and ranges etc. are used in conjunction with terms such as about, around, generally, substantially, essentially, at least etc. (i.e., “about 3” shall also cover exactly 3 or “substantially constant” shall also cover exactly constant).

Use of exemplary language, such as “for instance”, “such as”, “for example” (“e.g.,”) and the like, is merely intended to better illustrate the invention and does not indicate a limitation on the scope of the invention unless specifically so claimed.

While the invention has been described in connection with what is presently considered to be the most practical and preferred embodiments, it is to be understood that the invention is not to be limited to the disclosed embodiment, but on the contrary, is intended to cover various modifications and equivalent arrangements included within the spirit and scope of the appended claims.

What is claimed is:

1. A display system for emitting light, comprising:
at least one printed circuit board (PCB) including a PCB first side and a PCB second side opposite the PCB first side;
at least one first light emitting diode (LED) configured with the PCB first side and adapted to emit first light in a first direction;
at least one second LED configured with the PCB second side and adapted to emit second light in a second direction; and
at least one first light guide configured with the at least one second LED and adapted to redirect at least a portion of the second light to the first direction as redirected light;
wherein the first light and the redirected light combine to form a total emitted light.

2. The display system of claim 1 wherein the second direction is opposite the first direction.

3. The display system of claim 1 further comprising a frame, wherein the at least one PCB is configured within the frame, wherein a peripheral edge of the at least one PCB is separated from the frame by a gap, and wherein the at least one first light guide is adapted to emit the redirected light through the gap.

4. The display system of claim 3 wherein the at least one second LED is positioned adjacent to the peripheral edge and adapted to emit second light into an input of the at least one first light guide.

5. The display system of claim 3 wherein the at least one first light guide is coupled to the frame.

6. The display system of claim 3 wherein the gap includes an encapsulate.

7. The display system of claim 1 further comprising an optics assembly adapted to affect the first light and/or the redirected light.

8. The display system of claim 1 wherein the at least one light guide includes one or more reflective prisms.

9. The display system of claim 8 wherein the one or more reflective prisms includes a first 45° reflective prism and a second 45° reflective prism opposing the first 45° reflective prism.

10. The display system of claim 1 wherein the at least one first light guide redirects the at least a portion of the second light 180°.

11. The display system of claim 1 wherein the at least one first LED includes an array of the at least one first LEDs and the at least one second LED includes a plurality of the at least one second LEDs arranged about a periphery of the at least one PCB.

12. The display system of claim 11 wherein the at least one first light guide includes a plurality of the at least one first light guides and wherein each one of the plurality of the at least one second LEDs is configured with a corresponding one of the plurality of the at least one first light guides.

13. A display system for emitting light, comprising:
a printed circuit board (PCB) having a front side and a rear side;
a front light emitting diode (LED) array that is mounted to the PCB front side and that emits forwardly directed light;
a rear light emitting diode (LED) array that is mounted to the PCB rear side and that emits rearwardly directed light; and
a light guide that is configured to redirect at least a portion of the rearwardly directed light in a forward direction thereby providing redirected light;
wherein the forwardly directed light and the redirected light are combined to form a complete displayed image.

14. The display system of claim 13, wherein the display system is a television or flat screen monitor.

15. The display system of claim 13, wherein the rearwardly directed light comprises pixel information, such that after the rearwardly directed light has been redirected to provide redirected light, the redirected light provides a continuation of an image provided by the forwardly directed light.
